(19) United States
(12) Patent Application Publication
(10) Pub. No.: US 2006/0215377 A1
(43) Pub. Date: Sep. 28, 2006

(54) Flexible circuit substrate and method of manufacturing the same

(75) Inventors: Tomohiro Nomura, Nagano-shi (JP); Kazunori Abe, Nagano-shi (JP); Shozo Yamamuro, Ushiku-shi (JP)

Correspondence Address: RANKIN, HILL, PORTER & CLARK LLP, 4080 ERIE STREET, WILLOUGHBY, OH, 44094-7836, US

(73) Assignee: Shinko Electric Industries Co., Ltd., Nagano-shi (JP)

(21) Appl. No.: 11/386,585

(22) Filed: Mar. 22, 2006

(30) Foreign Application Priority Data
Mar. 23, 2005 (JP) 2005-083590

(51) Int. Cl. H05K 7/00

(52) U.S. Cl. 361/748

(57) ABSTRACT

A wiring layer forming wirings containing inner leads and outer leads are formed on a flexible substrate. Then, inner lead reinforcing electrodes to which a semiconductor chip is connected are formed on the inner leads, outer lead reinforcing electrodes are formed on the outer leads, and wiring reinforcing portions are formed between the inner leads and the outer leads on the wiring layers. The flexible substrate is mounted onto an electronic device by folding a portion to which the wiring reinforcing portions are provided between the inner leads and the outer leads.

The present application claims foreign priority based on Japanese Patent Application No. 2005-083590, filed Mar. 23, 2005, the content of which is incorporated herein by reference.

### BACKGROUND OF THE INVENTION

1. Technical Field

The present invention relates to a flexible circuit substrate and a method of manufacturing the same and, more particularly, a flexible circuit substrate that is applicable in a COF (Chip On Film) package and a method of manufacturing the same.

2. Related Art

In recent years, employment of the COF (Chip On Film) system in substitution for the TAB (Tape Automated Bonding) system is increasing in the driver IC package in the liquid crystal display device, and the like. This COF system is ready to fit in with a fine pitch between wirings and is excellent in foldability

In the COF package manufacturing method in the related art, as shown in FIG. 10, firstly, a wiring layer 102 forming wirings containing inner leads 102a and outer leads 102b is formed by patterning a copper layer of a polyimide tape 100, on which a copper layer having a film thickness of 8 to 12 μm is covered, by means of the photolithography. Then, a cover coating layer 104 is formed on the wiring layer 102 such that the inner leads 102a and the outer leads 102b are exposed.

Then, as shown in FIG. 11, a resist film 106 in which a slit-like continuous opening portion 106a is provided to expose portions of the inner leads 102a, to which a semiconductor chip is connected, is formed thereon. Then, as shown in FIG. 12, bumps 108 are formed by applying the Cu plating to the portions of the inner leads 102a exposed in the opening portion 106a of the resist film 106. Then, the resist film 106 is removed, and then the Ni plating and then Au plating are applied to the bumps 108 and the wiring layer 102 exposed from the cover coating layer 104. As a result, as shown in FIG. 13, a COF type flexible circuit substrate having the bumps 108 that are connected to the semiconductor chip on the inner leads 102a is obtained.

[Patent Literature 1] JP-A-2003-142535

[Patent Literature 2] JP-A-2004-327936

[Patent Literature 3] JP-A-2004-328001

Recently a finer pitch between the wirings of wiring layer is requested. In case the normal polyimide tape with a copper layer is used, a film thickness of the copper layer is relatively thick (8 to 12 μm). Therefore, there exists the problem that such polyimide tape cannot easily fit in with a finer pitch between the wirings of wiring layer.

As the countermeasure against this problem, an approach of reducing a thickness of the overall copper layer up to a film thickness, which permits to form a fine-pitch pattern, by means of half-etching and then patterning the resultant copper layer is considered. In this case, it is possible that reliability of the wiring layer is lowered in mounting the COF package since a film thickness of the wiring layer becomes small. In particular, it is feared that reliability of the wiring layer is decreased due to disconnection of the outer lead portions, which are connected to connection terminals of an electronic device, and a folded portion of the wiring layer in folding the COF package and mounting it.

### SUMMARY OF THE INVENTION

The present invention has been made in view of the above circumstances, and it is an object of the present invention to provide a flexible circuit substrate that is able to deal easily with a finer pitch between wirings of a wiring layer and also is applicable in a COF package having the wiring layer with high reliability and a method of manufacturing the same.

However, the present invention need not achieve the above objects, and other objects not described herein may also be achieved. Further, the invention may achieve no disclosed objects without affecting the scope of the invention.

In order to overcome the above problems, the present invention is concerned with a flexible circuit substrate, which includes a flexible substrate; a wiring layer formed on the flexible substrate and forming wirings including inner leads and outer leads; an inner lead reinforcing electrode formed on the inner leads; an outer lead reinforcing electrode formed on the outer leads; a wiring reinforcing portion formed between the inner leads and the outer leads on the wiring layer; and a cover coating layer for covering the wiring layer to expose the inner leads and the outer leads; wherein the flexible substrate is mounted onto an electronic device by folding a portion to which the wiring reinforcing portion is provided between the inner leads and the outer leads.

In order to manufacture the flexible circuit substrate of the present invention, firstly, the flexible substrate (polyimide tape, or the like) on one surface of which the thin (e.g., 1 to 5 μm) metal layer, which permits to form the wirings of wiring layer at a desired wiring pitch, is formed is prepared. Then, the wiring layer is formed by patterning the metal layer by means of the photolithography. Then, the resist film in which the opening portions to define the reinforced portions of the wirings of thin wiring layer are provided independently on the wirings of wiring layer is formed. Then, the metal plating layer is formed selectively on the opening portions in the resist film, and then the resist film is removed.

Accordingly, the inner lead reinforcing electrodes acting as the bumps to which the semiconductor chip is connected are formed on the inner leads of the wiring layer. Also, the wiring reinforcing portions are formed on the center portions of the wiring layer. In addition, the outer lead reinforcing electrodes acting as the external connection terminals are formed on the outer leads.

In the flexible circuit substrate of the present invention, a finer pitch (line: space=20:20 μm or less) between wirings of the wiring layer can be achieved by forming the major wiring layer as a thin film, and also reliability of the portions of the wiring layer, which have some fear for their reliability, can be ensured by stacking the metal plating layer thereon to reinforce.

Since the wiring layer is formed of a thin film but the inner lead reinforcing portions are provided to the inner leads, the semiconductor chip can be connected electrically to the inner leads with good reliability. Also, since the outer lead reinforcing portions are provided to the outer leads, the outer leads can be connected electrically to the connection terminals of the electronic device with good reliability.

In addition, even when the flexible circuit substrate is folded between the inner leads and the outer leads and mounted onto the electronic device, the faults such as the disconnection of the wirings of wiring layer, and the like are never caused and reliability of the wiring layer can be still secured since the wiring reinforcing portions are provided to the folded portion of the wiring layer.

In Patent Literatures 1 to 3, it is set forth that the projected connection electrodes are formed by formed wirings on the film base material, then forming the resist film in which openings are provided on the wirings, and then forming the plating layer in the openings. However, in Patent Literatures 1 to 3, no consideration is given to the technology that permits to get a fine pitch between the wirings of wiring layer and also reinforces the folded portion of the wiring layer to secure reliability in folding and mounting the film base material. These Literatures do not suggest the configuration of the present invention at all.

As described above, according to the flexible circuit substrate of the present invention, the wirings of wiring layer can be formed easily at a desired fine pitch and also high reliability of the wiring layer can be attained in applying the folded mounting.

### BRIEF DESCRIPTION OF THE DRAWINGS

FIG. 1 is a view (#1) showing a method of manufacturing a flexible circuit substrate according to a first exemplary, non-limiting embodiment of the present invention.

FIG. 2 is a view (#2) showing the method of manufacturing the flexible circuit substrate according to the first exemplary, non-limiting embodiment of the present invention.

FIG. 3 is a view (#3) showing the method of manufacturing the flexible circuit substrate according to the first exemplary, non-limiting embodiment of the present invention.

FIG. 4 is a view (#4) showing the method of manufacturing the flexible circuit substrate according to the first exemplary, non-limiting embodiment of the present invention.

FIG. 5 is a view (#5) showing the method of manufacturing the flexible circuit substrate according to the first exemplary, non-limiting embodiment of the present invention.

FIG. 6 is a view showing a situation that a semiconductor chip is mounted on the flexible circuit substrate according to the first exemplary, non-limiting embodiment of the present invention.

FIG. 7 is a sectional view showing a situation that the flexible circuit substrate according to the first exemplary, non-limiting embodiment of the present invention, on which the semiconductor chip is mounted, is folded and packaged in an electronic equipment.

FIG. 8 is a view (#1) showing a method of manufacturing a flexible circuit substrate according to a second exemplary, non-limiting embodiment of the present invention.

FIG. 9 is a view (#2) showing the method of manufacturing the flexible circuit substrate according to the second exemplary, non-limiting embodiment of the present invention.

FIG. 10 is a view (#1) showing a method of manufacturing a COF package in the related art.

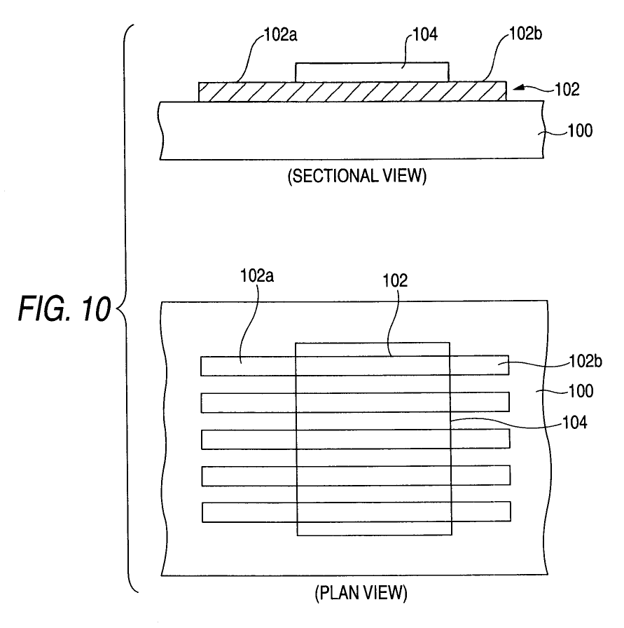

FIG. 11 is a view (#2) showing the method of manufacturing the COF package in the related art.

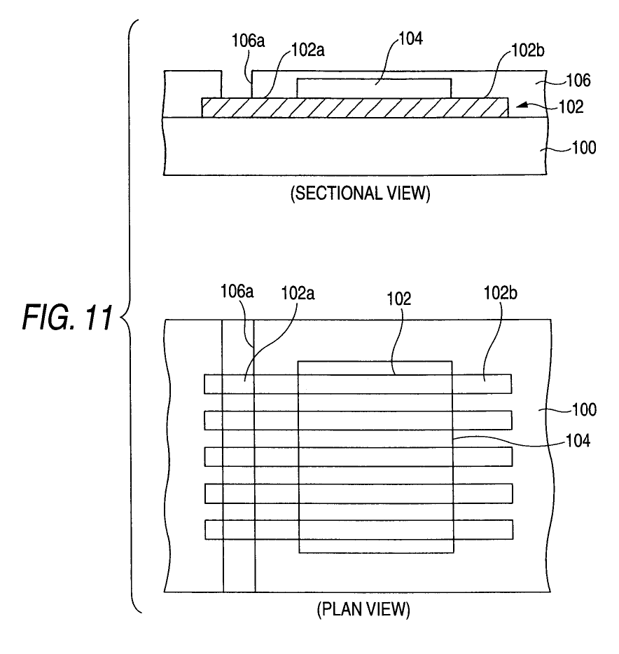

FIG. 12 is a view (#3) showing the method of manufacturing the COF package in the related art.

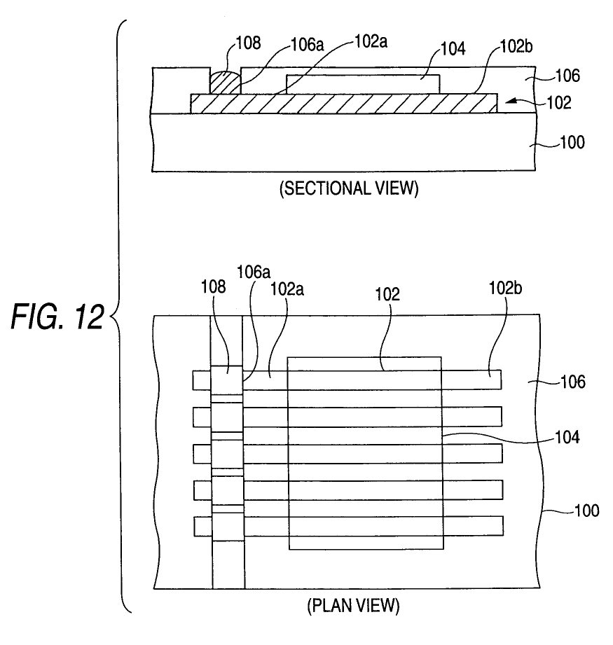

FIG. 13 is a view (#4) showing the method of manufacturing the COF package in the related art.

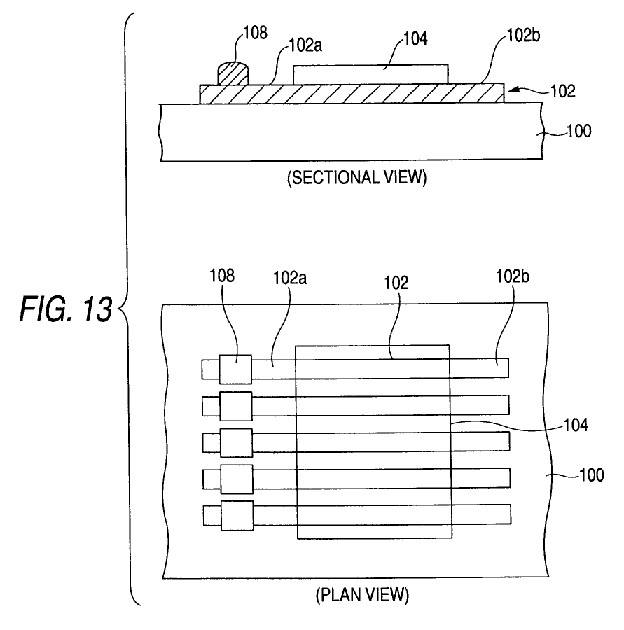

### DETAILED DESCRIPTION OF THE INVENTION

Embodiments of the present invention will be explained with reference to the accompanying drawings hereinafter.

### First Embodiment

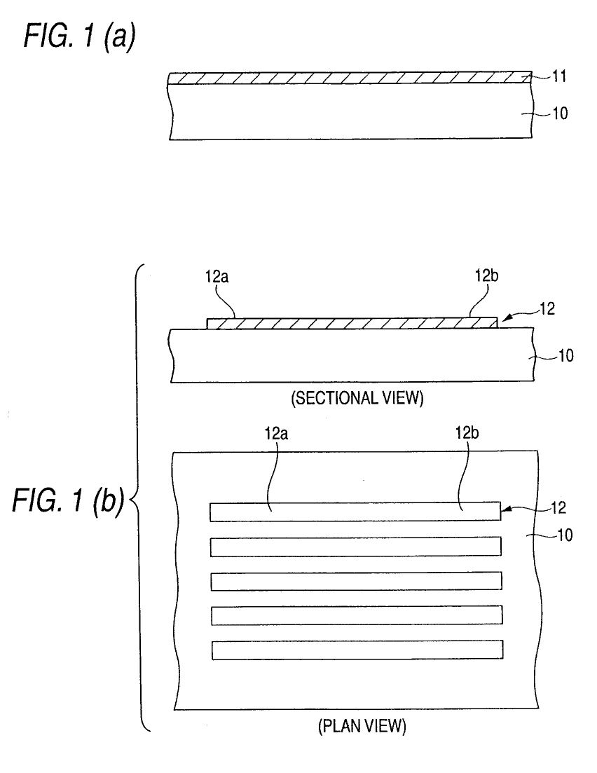

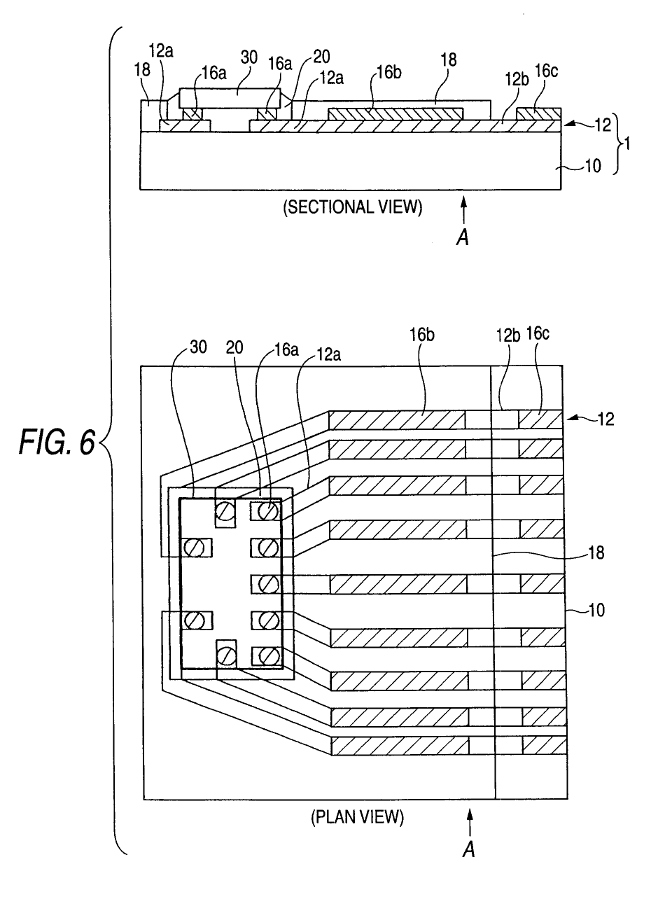

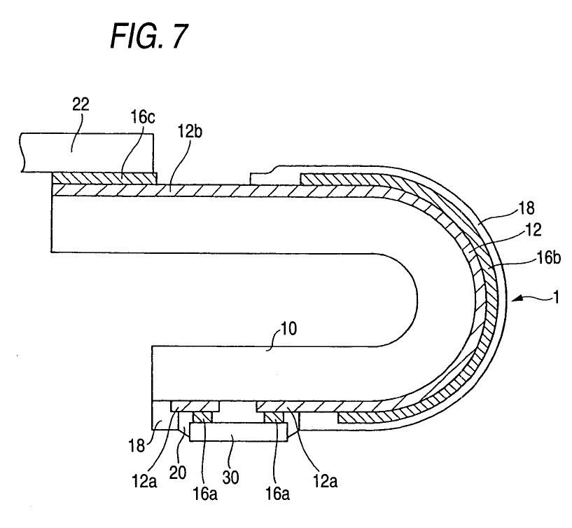

FIG. 1 to FIG. 5 are views showing a method of manufacturing a flexible circuit substrate according to a first exemplary, non-limiting embodiment of the present invention. FIG. 6 and FIG. 7 are views showing a situation that a semiconductor chip is mounted on the flexible circuit substrate according to the first exemplary, non-limiting embodiment of the present invention. In the method of manufacturing the flexible circuit substrate of the first exemplary, non-limiting embodiment of the present invention, as shown in FIG. 1(a), firstly, a polyimide tape (flexible substrate) 10 on one surface of which a metal layer 11 made of copper (Cu) is formed is prepared. As the metal layer 11, a thin metal layer having a film thickness of 1 to 5 μm (preferably 2 to 3 μm) is used such that wiring layer forming wirings with a desired wiring pitch (wiring pattern) can be formed.

As the method of obtaining the polyimide tape 10 with such metal layer 11, there is the method that a thin metal layer having a film thickness of 1 to 5 μm is obtained by coating a polyimide varnish on a copper foil, then curing the varnish, and then applying the half-etching to the copper foil. Alternately, the thin metal layer having a film thickness of 1 to 5 μm may be obtained by forming a copper on the polyimide tape by means of the sputter, and then applying the electrolytic copper plating using the sputter film as the power feeding layer.

Then, as shown in FIG. 1(b), a wiring layer (wiring pattern) 12 is formed by patterning the metal layer 11 by virtue of the photolithography and the etching. At this time, since the film thickness of the metal layer 11 is thinned to such extent that the wiring pattern can be formed at a fine pitch, the fine wiring layer 12 (line: space=20:20 μm or less) can be readily formed. The wiring layer 12 is formed to form the wirings including inner leads 12a to which a semiconductor chip is connected and outer leads 12b to which connection terminals of an electronic device are connected.

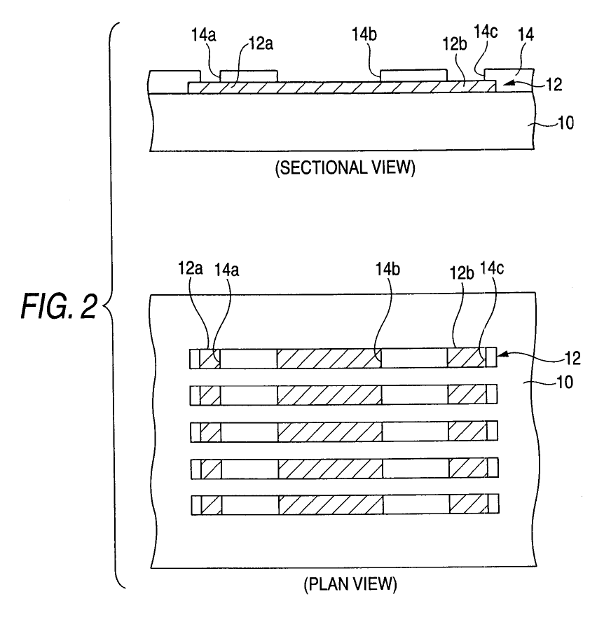

One feature of the present embodiment is that the fine wiring layers 12 is formed by using the thin metal layer 11 and a metal layer is stacked on portions of the wiring layer 12, which have some fear for their reliability, to reinforce them. In other words, as shown in FIG. 2, a resist film 14 in which first to third opening portions 14a to 14c (hatched portions in a plan view of FIG. 2) are provided on reinforced portions of the wiring layer 12 is formed. The first opening portions 14a of the resist film 14 are formed on connection portions of the inner leads 12a. The second opening portions 14b are formed on center reinforced portions of the wiring layer 12. The third opening portion 14c are formed on connection portions of the outer leads 12b.

In the present embodiment, since a film thickness of the underlying wiring layer 12 is thin upon forming the resist film 14 and thus a level difference is small, the overall wiring layer 12 can be covered sufficiently with the relatively thin resist film 14 not to expose shoulder portions of the wiring layer 12 and also an enough focal depth in the photolithography can be obtained. Therefore, the fine opening portions 14a to 14c can be formed to be aligned with the wirings of wiring layer 12 with high precision. In other words, in the present embodiment, unlike the related art, the resist film 14 in which opening portions, a size of which is equal to or smaller than a width of the each wiring of wiring layer 12, are provided independently on the wirings of wiring layer 12 respectively can be easily patterned. This resist film 14 may be formed by coating a photosensitive liquid resist or laminating a photosensitive dry film resist.

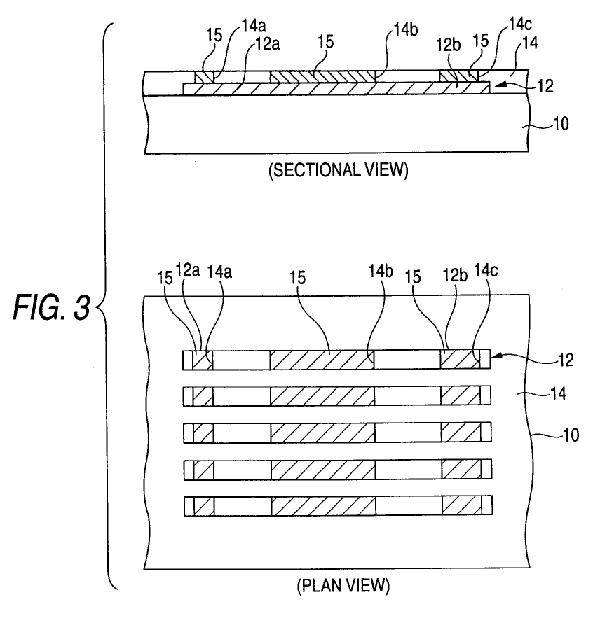

Then, as shown in FIG. 3, metal plating layers 15 (hatched portion in a plan view in FIG. 3) are formed on respective portions of the wiring layer 12, which are exposed from the first to third opening portions 14a to 14c of the resist film 14, by the electrolytic plating using the wiring layer 12 as a plating power feeding layer. This metal plating layer 15 is made of Cu, or the like whose film thickness is about 9 μm. Here, the film thickness of the metal plating layer 15 is 3 to 20 μm, preferably, 5 to 10 μm. Here, although not particularly shown in FIG. 3, the wirings of wiring layer 12 are connected to a common plating power feeding portion, and the plating power feeding portion is disconnected later to give the individual wirings of wiring layer 12. Then, the resist film 14 is removed.

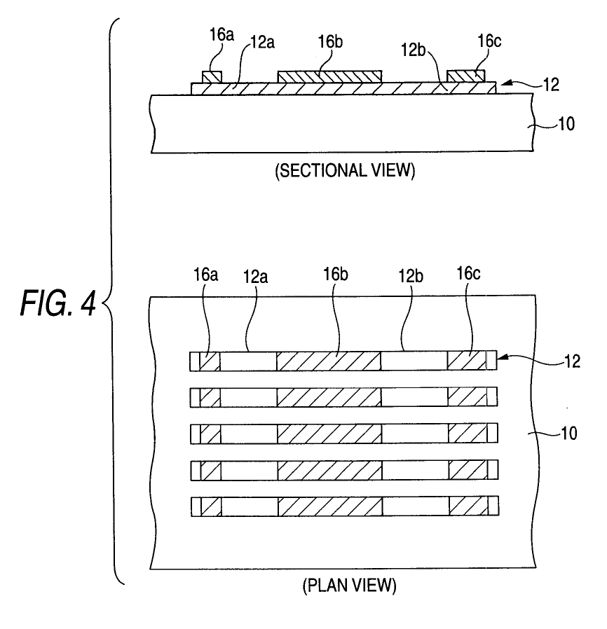

Accordingly, as shown in FIG. 4, inner lead reinforcing electrodes 16a acting as the bumps are formed on the inner leads 12a of the wiring layer 12. Also, wiring reinforcing portions 16b are formed on the center portions of the wiring layer 12. Also, outer lead reinforcing electrodes 16c acting as the external connection terminals are formed on the outer leads 12b.

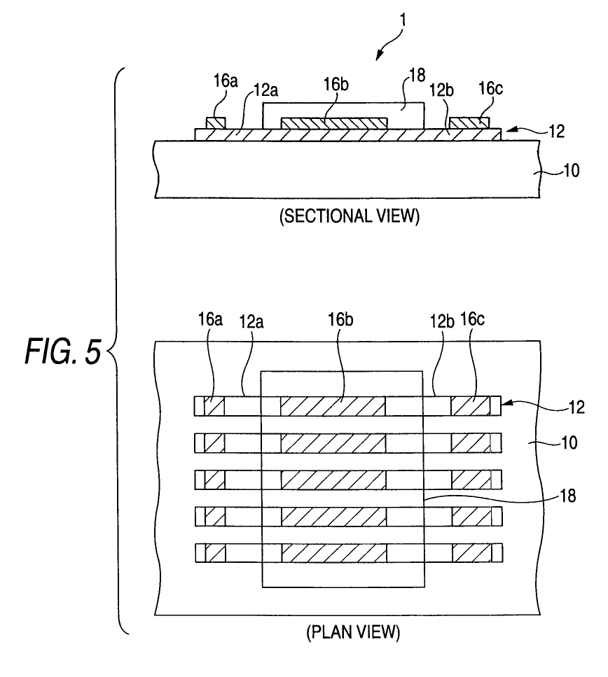

Then, as shown in FIG. 5, a cover coating layer 18 is formed by the solder resist to over the center portion containing the wiring reinforcing portions 16b of the wiring layer 12 such that the inner leads 12a and the outer leads 12b are exposed. Then, the Ni plating and then Au plating are applied to the inner leads 12a and the outer leads 12b (containing respective reinforcing electrodes 16a, 16c) that are exposed from the cover coating layer 18.

Consequently, a flexible circuit substrate 1 of the present embodiment is obtained.

As described above, in the method of manufacturing the flexible circuit substrate of the present embodiment, first the polyimide tape 10 on one surface of which the metal layer 11, whose film thickness is reduced to such extent that the wiring pattern can be formed at a fine pitch, is formed is prepared. Then, the wiring layer 12 is formed by patterning the metal layer 11 by means of the photolithography. In the present embodiment, since the thin metal layer 11 is employed, the wiring layer 12 forming wirings with a fine pitch therebetween (line: space=20:20 μm or less) can be readily formed.

Then, the resist film 14 in which the first to third opening portions 14a to 14c used to define the reinforced portions of the wiring layer 12 are provided on the wiring layer 12 is formed. At this time, the fine patterns can be formed since the resist film 14 is formed on the wiring layer 12 constituting a small level difference, and the independent opening portions 14a to 14c are formed on the wirings of wiring layer 12 respectively. Also, the metal plating layer 15 is formed selectively in the opening portions 14a to 14c in the resist film 14, and then the resist film 14 is removed.

Accordingly, the inner lead reinforcing electrodes 16a acting as the bumps to which the semiconductor device is connected are formed on the inner leads 12a of the wiring layer 12. Also, wiring reinforcing portions 16b are formed on the center portions of the wiring layer 12. Also, the outer lead reinforcing electrodes 16c acting as the external connection terminals are formed on the outer leads 12b.

In the present embodiment, unlike the case the resist film having the slit-like opening portion that extends over a plurality of wirings of wiring layer is formed in the related art, the mutually independent opening portions 14a to 14c can be formed in the resist film 14 on the wiring layer 12. Therefore, since the metal plating layer 15 is formed not to enlarge toward the neighboring wiring of wiring layer 12, there is no chance that the wirings of wiring layer 12 are electrically short-circuited even when the wirings of wiring layer 12 are formed at a finer pitch.

An example in which the semiconductor chip is mounted onto the flexible circuit substrate of present embodiment is shown in FIG. 6. As shown in FIG. 6, in the flexible circuit substrate 1 of present embodiment, the wiring layer 12 forming the wirings containing the inner leads 12a and the outer leads 12b is formed on the polyimide tape 10. The inner leads 12a are led via the wiring layer 12 and connected to the outer leads 12b provided collectively on one end side respectively.

The inner lead reinforcing electrodes 16a arranged in the area on which the semiconductor chip is mounted are provided to the inner leads 12a. Also, the outer lead reinforcing electrodes 16c acting as the external connection terminals that are connected to the electronic device are provided to the outer leads 12b. Also, the wiring reinforcing portions 16b are provided to the center portions of the wiring layer 12.

The cover coating layer 18 is formed on the wiring layer 12 such that the area in which the inner lead reinforcing electrodes 16a are arranged (semiconductor chip mounting area) and the outer leads 12b are exposed. Then, a semiconductor chip 30 is flip-chip connected to the inner lead reinforcing electrodes 16a, and an underfill resin 20 is filled into a clearance produced under the semiconductor chip 30.

In the flexible circuit substrate of the present embodiment, since the polyimide tape 10 is used as the flexible substrate, the flexible circuit substrate can be mounted onto various electronic devices in its folded state. A situation that the flexible circuit substrate on which the semiconductor chip shown in FIG. 6 is mounted is connected to the electronic device in its folded state is shown in FIG. 7. As shown in FIG. 7, the flexible circuit substrate 1 on which the semiconductor chip shown in FIG. 6 is mounted is folded at a folded portion A in FIG. 6 (portion on which the wiring reinforcing portions 16b are provided) to direct the semiconductor chip 30 and the outer leads 12b outward. Then, the outer lead reinforcing electrodes 16c on the outer leads 12b are connected electrically to connection terminals 22 of the electric device (the driver circuit of the liquid crystal display device, or the like) and mounted thereon. Since the flexible circuit substrate is mounted in this manner, an area of the circuit substrate on which the semiconductor chip is mounted can be reduced. Therefore, a miniaturization of the electronic device such as the liquid crystal display device, or the like can be attained.

In the flexible circuit substrate 1 of the present embodiment, a finer pitch between the wirings of wiring layer 12 can be realized by forming the main wiring layer 12 by a thin film, and also reliability can be assured by stacking the metal plating layers 15 on the portions of the wiring layer 12, which have some fear for their reliability, to reinforce.

Since the inner lead reinforcing electrodes 16a are formed on the inner leads 12a, the semiconductor chip 30 can be connected electrically to the inner leads 12a with good reliability. Also, since the outer lead reinforcing electrodes 16c are provided onto the outer leads 12b, the outer leads 12b can be connected electrically to the connection terminals 22 of the electronic device with good precision. In addition, since the wiring reinforcing portions 16b are provided to the wiring layer 12 located at the folded portion A, faults such as the disconnection of the wirings of wiring layer 12, and the like are never caused and reliability of the wiring layer 12 can be secured even when the flexible circuit substrate 1 is folded and mounted.

As described above, in the present embodiment, a finer pitch of the wirings of wiring layer 12 on the flexible circuit substrate can be easily achieved and also reliability of the electrical connection between the inner leads 12a and the semiconductor chip 30 and the electrical connection between the outer leads 12b and the electronic device can be improved. Further, reliability of the wiring layer 12 in mounting in its folded state can be improved.

### Second Embodiment

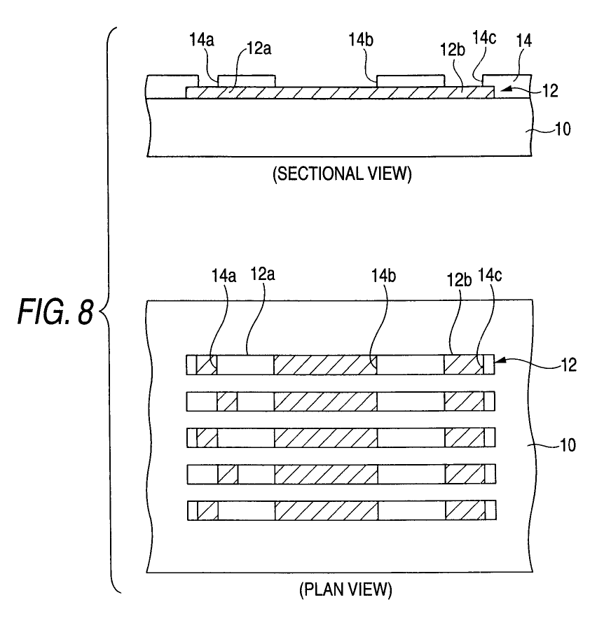

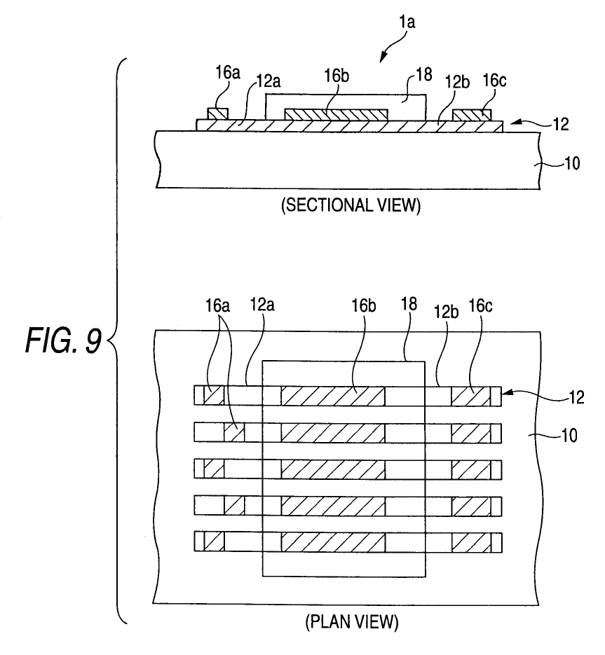

FIG. 8 and FIG. 9 are views showing a method of manufacturing a flexible circuit substrate according to a second exemplary, non-limiting embodiment of the present invention. A difference of the second embodiment from the first embodiment resides in that the inner lead reinforcing electrodes are aligned in a zigzag. In the second embodiment, detailed explanation of the similar steps to the first embodiment will be omitted herein.

As shown in FIG. 8, like the first embodiment, firstly, the wiring layer 12 forming the wirings containing the inner leads 12a and the outer leads 12b is formed on one surface of the polyimide tape 10, and then the resist film 14 in which the first to third opening portions 14a to 14c are provided on the reinforced portions of the wiring layer 12 is formed (hatched portions in a plan view of FIG. 8). In the second embodiment, in order to arrange the inner lead reinforcing electrodes in a zigzag, the first opening portions 14a of the resist film 14 are aligned in a zigzag in respective neighboring positions of the inner leads 12a.

Then, the steps shown in FIG. 3 to FIG. 5 explained in the first embodiment are carried out. Thus, as shown in FIG. 9, the inner lead reinforcing electrode 16a are formed to be aligned with the inner leads 12a in a so-called stagger alignment respectively in a state that the inner lead reinforcing electrode 16a are staggered in the direction perpendicular to the inner leads 12a. Consequently, a flexible circuit substrate la of the second embodiment is obtained.

In this way, unlike the related art, in the present embodiment, the opening portions 14a to 14c of the resist film 14 can be formed independently on the wirings of wiring layer 12 respectively. Therefore, the inner lead reinforcing electrode 16a can be formed in any positions of the inner leads 12a to be aligned mutually with high precision. In this case, not only the inner lead reinforcing electrode 16a but also the wiring reinforcing portions 16b and the outer lead reinforcing electrodes 16c can be placed in any positions of the wiring layer 12.

In the second embodiment, the inner lead reinforcing electrode 16a are arranged in a zigzag. Therefore, even when the inner lead reinforcing electrode 16a are formed to jut out from the inner leads 12a, it is hard for the electrical short-circuit to occur between neighboring inner lead reinforcing electrode 16a. Therefore, a further fine pitch between the wirings of wiring layer 12 can be achieved.

It will be apparent to those skilled in the art that various modifications and variations can be made to the described preferred embodiments of the present invention without departing from the spirit or scope of the invention. Thus, it is intended that the present invention cover all modifications and variations of this invention consistent with the scope of the appended claims and their equivalents.

I/We claim:

1. A flexible circuit substrate, comprising:
a flexible substrate;
a wiring layer formed on the flexible substrate and forming wirings including inner leads and outer leads;
an inner lead reinforcing electrode formed on the inner leads;
an outer lead reinforcing electrode formed on the outer leads;
a wiring reinforcing portion formed between the inner leads and the outer leads on the wiring layer; and
a cover coating layer for covering the wiring layer to expose the inner leads and the outer leads;
wherein the flexible substrate is mounted onto an electronic device by folding a portion to which the wiring reinforcing portion is provided between the inner leads and the outer leads.

2. A flexible circuit substrate according to claim 1, wherein a semiconductor chip is connected to the inner lead reinforcing electrode and the outer lead reinforcing electrode is connected to a connection terminal of the electronic device.

3. A flexible circuit substrate according to claim 1, wherein a film thickness of the wiring layer is 1 to 5 μm, and the wirings of wiring layer are formed to have a line: space=20:20 μm or less.

4. A flexible circuit substrate, according to claim 1, wherein the flexible substrate is formed of a polyimide tape, and the wiring layer, the inner lead reinforcing electrode, the outer lead reinforcing electrode, and the wiring reinforcing portion are made of copper.

5. A method of manufacturing a flexible circuit substrate, comprising:
preparing a flexible substrate on one surface of which a metal layer is formed, and then forming a wiring layer forming wirings containing inner leads and outer leads by patterning the metal layer;
forming a resist film in which opening portions are provided in portions of the inner leads of the wiring layer, a portion containing a folded portion of the wiring layer between the inner leads and the outer leads, and portions of the outer leads respectively;
forming a metal plating layer in portions of the wiring layer, which are exposed from the opening portions, to obtain an inner lead reinforcing electrode formed on the portions of the inner leads, a wiring reinforcing portion formed on the folded portion of the wiring layer, and an outer lead reinforcing electrode formed on the portions of the outer leads; and
removing the resist film.

6. A method of manufacturing a flexible circuit substrate, according to claim 5, after the step of removing the resist film, further comprising:
forming a cover coating layer for covering the wiring layer to expose the inner leads and the outer leads.

7. A method of manufacturing a flexible circuit substrate, according to claim 5, wherein, in the step of forming the resist film, the opening portions in the resist are formed independently every the wirings of wiring layer.

8. A method of manufacturing a flexible circuit substrate, according to claim 5, wherein a film thickness of the wiring layer formed on the flexible substrate is 1 to 5 μm, and the wirings of wiring layer are formed to have a line: space=20:20 μm or less.

9. A method of manufacturing a flexible circuit substrate, according to claim 5, wherein the flexible substrate is formed of a polyimide tape, and the metal layer and the metal plating layer are made of copper.
